(19) United States
(12) Patent Application Publication
(10) Pub. No.: US 2024/0030252 A1
(43) Pub. Date: Jan. 25, 2024

(54) SOLID-STATE IMAGING DEVICE AND ELECTRONIC APPARATUS

(71) Applicant: SONY SEMICONDUCTOR SOLUTIONS CORPORATION, Kanagawa (JP)

(72) Inventor: Yusuke MORIYA, Kumamoto (JP)

(73) Assignee: SONY SEMICONDUCTOR SOLUTIONS CORPORATION, Kanagawa (JP)

(21) Appl. No.: 18/249,353

(22) PCT Filed: Sep. 3, 2021
(86) PCT No.: PCT/JP2021/032449

§ 371 Date: Apr. 17, 2023

(30) Foreign Application Priority Data
Oct. 28, 2020 (JP) 2020-180833

(51) Int. Cl. H01L 27/146

(52) U.S. Cl. CPC H01L 27/14627; H01L 27/14645; H01L 27/1462; H01L 27/14621; H01L 27/1463; H01L 27/14685

(57) ABSTRACT

Provided is a solid-state imaging device capable of improving the quantum efficiency while reducing an inter-same-color sensitivity difference. Provided are: a substrate; a plurality of photoelectric conversion units formed on the substrate; a microlens array including a plurality of microlenses formed on one surface side of the substrate for a photoelectric conversion unit group including at least two or more of the adjacent photoelectric conversion units; and a trench portion which has a lattice shape and is formed in the substrate to surround each of the photoelectric conversion units. Furthermore, the microlens is formed by laminating two or more lens layers having different refractive indexes. Furthermore, out of the two or more lens layers, a lens layer closer to the substrate has a lower refractive index.

### TECHNICAL FIELD

The present technology relates to a solid-state imaging device and an electronic apparatus.

### BACKGROUND ART

Conventionally, a solid-state imaging device having a structure in which one microlens is shared by four adjacent photoelectric conversion units is proposed (see, for example, Patent Document 1). In the solid-state imaging device described in Patent Document 1, a distance to a subject can be calculated on the basis of a difference among signal charges of the four photoelectric conversion units. Therefore, all pixels can be used as autofocus sensors.

Furthermore, the solid-state imaging device described in Patent Document 1 includes a lattice-shaped pixel separation portion surrounding each of the photoelectric conversion units.

### CITATION LIST

### Patent Document

Patent Document 1: Japanese Patent Application Laid-Open No. 2013-211413

### SUMMARY OF THE INVENTION

### Problems to be Solved by the Invention

In the solid-state imaging device described in Patent Document 1, however, for example, there is a possibility that a center of a light-condensed spot of incident light deviates from centers of the four photoelectric conversion units due to a variation in a width of the pixel separation portion, a variation in a position of the pixel separation portion, an overlay deviation between the pixel separation portion and the microlens, and the like. Therefore, there is a possibility that a difference in light receiving sensitivity (inter-same-color sensitivity difference) occurs between the photoelectric conversion units.

As a method for reducing such an inter-same-color sensitivity difference, for example, it is conceivable to widen the light-condensed spot of the incident light by increasing a curvature radius of the microlens, but there is a possibility that the quantum efficiency (QE) decreases since the light condensing power decreases.

An object of the present disclosure is to provide a solid-state imaging device and an electronic apparatus capable of improving the quantum efficiency while reducing an inter-same-color sensitivity difference.

### Solutions to Problems

A solid-state imaging device of the present disclosure includes: (a) a substrate; (b) a plurality of photoelectric conversion units formed on the substrate; (c) a microlens array including a plurality of microlenses formed on one surface side of the substrate for a photoelectric conversion unit group including at least two or more of the adjacent photoelectric conversion units; and (d) a trench portion which has a lattice shape and is formed in the substrate to surround each of the photoelectric conversion units, in which (e) two or more lens layers having different refractive indexes are laminated in the microlens, and (f) a lens layer closer to the substrate out of the two or more lens layers has a lower refractive index.

Furthermore, an electronic apparatus of the present disclosure includes a solid-state imaging device including: (a) a substrate; (b) a plurality of photoelectric conversion units formed on the substrate; (c) a microlens array including a plurality of microlenses formed on one surface side of the substrate for a photoelectric conversion unit group including at least two or more of the adjacent photoelectric conversion units; and (d) a trench portion which has a lattice shape and is formed in the substrate to surround each of the photoelectric conversion units, in which (e) two or more lens layers having different refractive indexes are laminated in the microlens, and (f) a lens layer closer to the substrate out of the two or more lens layers has a lower refractive index.

### BRIEF DESCRIPTION OF DRAWINGS

FIG. 1 is a diagram depicting an overall configuration of a solid-state imaging device according to a first embodiment.

FIG. 2 is a view depicting a cross-sectional configuration of a pixel region in a case of being taken along a line A-A of FIG. 1.

FIG. 3 is a view depicting a planar configuration of the pixel region in a case of being taken along a line B-B in FIG. 2.

FIG. 4 is a view depicting a planar configuration of the pixel region in a case where the solid-state imaging device is viewed in a plan view.

FIG. 5A is a view depicting each process of a method for manufacturing the solid-state imaging device according to the first embodiment.

FIG. 5B is a view depicting each process of the method for manufacturing the solid-state imaging device according to the first embodiment.

FIG. 5C is a view depicting each process of the method for manufacturing the solid-state imaging device according to the first embodiment.

FIG. 5D is a view depicting each process of the method for manufacturing the solid-state imaging device according to the first embodiment.

FIG. 6 is a view depicting a cross-sectional configuration of a pixel region of a solid-state imaging device according to a modified example.

FIG. 7 is a view depicting a cross-sectional configuration of a pixel region of a solid-state imaging device according to a modified example.

FIG. 8 is a view depicting a cross-sectional configuration of a pixel region of a solid-state imaging device according to a modified example.

FIG. 9 is a diagram depicting an overall configuration of an electronic apparatus according to a second embodiment.

FIG. 10 is a diagram depicting usage examples in which a CMOS image sensor is used.

FIG. 11 is a block diagram depicting an example of a schematic configuration of a vehicle control system.

FIG. 12 is a diagram of assistance in explaining an example of installation positions of an outside-vehicle information detecting section and an imaging section.

FIG. 13 is a view depicting an example of a schematic configuration of an endoscopic surgery system.

FIG. 14 is a block diagram depicting an example of a functional configuration of a camera head and a camera control unit (CCU).

### MODE FOR CARRYING OUT THE INVENTION

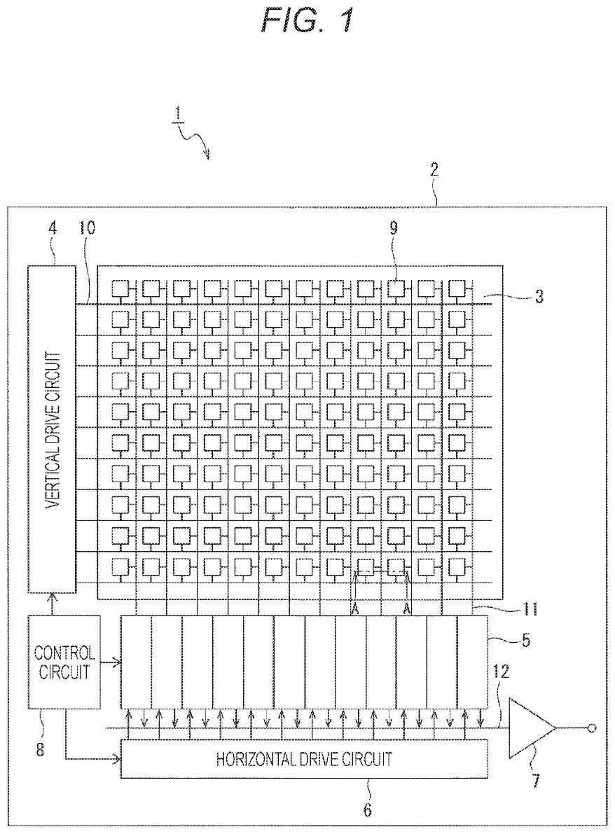

Hereinafter, examples of a solid-state imaging device and an electronic apparatus according to embodiments of the present disclosure will be described with reference to FIGS. 1 to 10. The embodiments of the present disclosure will be described in the following order. Note that the present disclosure is not limited to the following examples. Furthermore, effects described in the present specification are merely examples and are not limited, and other effects may be present.
1. First Embodiment: Solid-State Imaging Device
1-1 Overall Configuration of Solid-State Imaging Device
1-2 Configuration of Main Part
1-3 Method for Manufacturing Solid-State Imaging Device
1-4 Modified Examples
2. Example of Application to Electronic apparatus
2-1 Overall Configuration of Electronic apparatus
2-2 Usage Examples of CMOS Image Sensor
3. Example of Application to Mobile Body
4. Example of Application to Endoscopic Surgery System

### 1. First Embodiment

### [1-1 Overall Configuration of Solid-State Imaging Device]

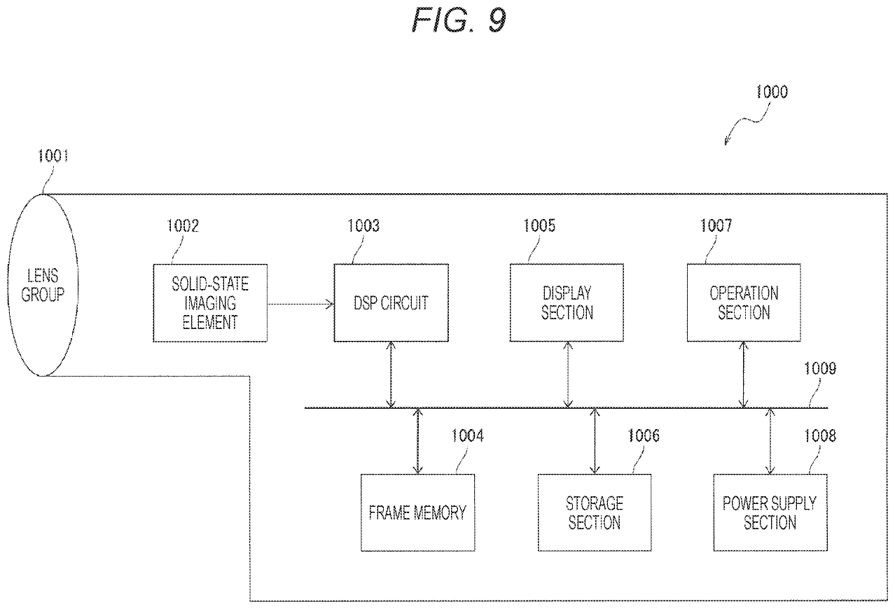

FIG. 1 is a diagram depicting an overall configuration of a solid-state imaging device according to a first embodiment of the present disclosure. A solid-state imaging device 1 in FIG. 1 is a complementary metal oxide semiconductor (CMOS) image sensor of a back-surface irradiation type. As depicted in FIG. 9, the solid-state imaging device 1 (solid-state imaging element 1002) takes image light (incident light) from a subject via a lens group 1001, converts a light amount of the incident light formed on an imaging surface into an electric signal in units of pixels, and outputs the electric signal as a pixel signal.

As depicted in FIG. 1, the solid-state imaging device 1 includes a pixel region 3 and a peripheral circuit unit arranged around the pixel region 3.

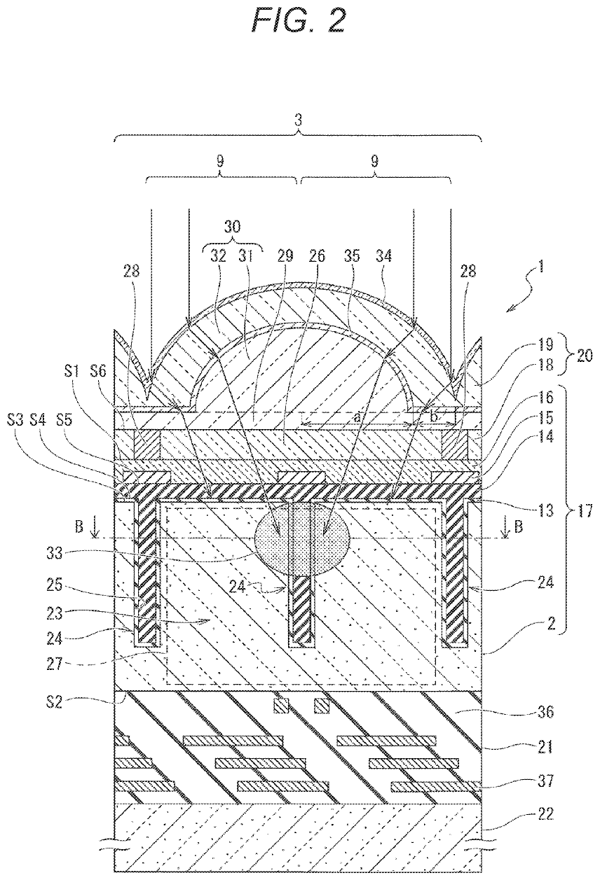

The pixel region 3 has a plurality of pixels 9 arrayed in a two-dimensional matrix on a substrate 2. The pixel 9 includes a photoelectric conversion unit 23 depicted in FIG. 2 and a plurality of pixel transistors (not depicted). As the pixel transistor, for example, four transistors of a transfer transistor, a reset transistor, a selection transistor, and an amplification transistor can be adopted.

The peripheral circuit unit includes a vertical drive circuit 4, a column signal processing circuit 5, a horizontal drive circuit 6, an output circuit 7, and a control circuit 8.

The vertical drive circuit 4 is configured using, for example, a shift register, selects a desired pixel driving wiring 10, supplies a pulse for driving the pixels 9 to the selected pixel driving wiring 10, and drives the respective pixels 9 in units of rows. That is, the vertical drive circuit 4 selectively scans each of the pixels 9 in the pixel region 3 sequentially in the vertical direction in units of rows, and supplies a pixel signal based on a signal charge generated in accordance with the amount of received light in the photoelectric conversion unit 23 of each of the pixels 9 to the column signal processing circuit 5 through a vertical signal line 11.

The column signal processing circuit 5 is arranged, for example, for each column of the pixels 9, and performs signal processing, such as noise removal, on signals output from the pixels 9 of one row for each pixel column. For example, the column signal processing circuit 5 performs signal processing such as correlated double sampling (CDS) and analog-digital (AD) conversion to remove fixed pattern noise unique to the pixel.

The horizontal drive circuit 6 is configured using, for example, a shift register, sequentially outputs horizontal scanning pulses to the column signal processing circuits 5, sequentially selects each of the column signal processing circuits 5, and causes each of the column signal processing circuits 5 to output the pixel signal, which has been subjected to the signal processing, to a horizontal signal line 12.

The output circuit 7 performs signal processing on the pixel signals sequentially supplied from the respective column signal processing circuits 5 through the horizontal signal line 12, and outputs the processed pixel signals. As the signal processing, for example, buffering, black level adjustment, column variation correction, various digital signal processing, and the like can be used.

The control circuit 8 generates a clock signal and a control signal serving as references of operations of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signal and control signal to the vertical drive circuit 4, the column signal processing circuit 5, the horizontal drive circuit 6, and the like.

### [1-2 Configuration of Main Part]

Next, a detailed structure of the solid-state imaging device 1 in FIG. 1 will be described. FIG. 2 is a view depicting a cross-sectional configuration of the pixel region 3 of the solid-state imaging device 1.

As depicted in FIG. 2, the solid-state imaging device 1 includes a light receiving layer 17 formed by laminating the substrate 2, a fixed charge film 13, an insulating film 14, a light shielding film 15, and a planarization film 16 in this order. Furthermore, a light condensing layer 20, formed by laminating a color filter layer 18 and a microlens array 19 in this order, is formed on a surface of the light receiving layer 17 on the planarization film 16 side (hereinafter, also referred to as a “back surface S1 side”) Moreover, a wiring layer 21 and a support substrate 22 are laminated in this order on a surface of the light receiving layer 17 on the substrate 2 side (hereinafter, also referred to as a “front surface S2 side”). Note that the back surface S1 of the light receiving layer 17 and a back surface of the planarization film 16 are the same surface, and thus, the back surface of the planarization film 16 is also referred to as the “back surface S1” in the following description. Furthermore, the front surface S2 of the light receiving layer 17 and a front surface of the substrate 2 are the same surface, and thus, the front surface of the substrate 2 is also referred to as the “front surface S2” in the following description.

The substrate 2 is configured using a semiconductor substrate including, for example, silicon (Si), and forms the pixel region 3. In the pixel region 3, the plurality of pixels 9 (square pixels) is arranged in a two-dimensional matrix. Each of the pixels 9 is formed on the substrate 2 and includes the photoelectric conversion unit 23 including a p-type semiconductor region and an n-type semiconductor region. The photoelectric conversion unit 23 forms a photodiode with a pn junction between the p-type semiconductor region and the n-type semiconductor region. Each of the photoelectric conversion units 23 generates a signal charge corresponding to a light amount of incident light on the photoelectric conversion unit 23, and accumulates the generated signal charge.

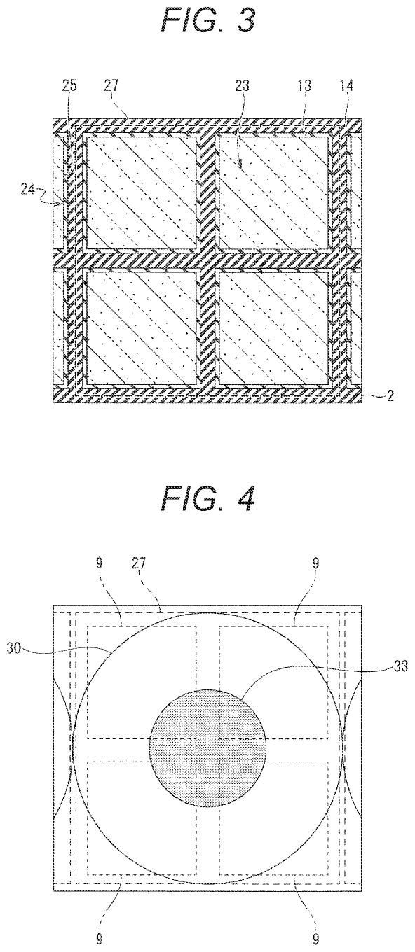

Furthermore, a pixel separation portion 24 is formed between the adjacent photoelectric conversion units 23. As depicted in FIG. 3, the pixel separation portion 24 is formed in a lattice shape so as to surround each of the photoelectric conversion units 23 with respect to the substrate 2. The pixel separation portion 24 has a bottomed trench portion 25 extending in a thickness direction from a back surface S3 side of the substrate 2. Side wall surfaces of the trench portion 25 form an outer shape of the pixel separation portion 24. That is, the trench portion 25 is formed in a lattice shape so as to surround each of the photoelectric conversion unit 23 with respect to the substrate 2. The fixed charge film 13 and the insulating film 14 are embedded inside the trench portion 25. Furthermore, a metal film that reflects light may be embedded in the insulating film 14. As the metal film, for example, tungsten (W) or aluminum (Al) can be adopted. Since the pixel separation portion 24 is adopted, each of the photoelectric conversion units 23 can be shielded from light, and optical color mixing can be suppressed.

The fixed charge film 13 continuously covers the entire back surface S3 side (the entire light incident surface side) of the substrate 2 and the inside of the trench portion 25. As a material of the fixed charge film 13, for example, hafnium (Hf), aluminum (Al), zirconium (Zr), tantalum (Ta), or titanium (Ti) can be adopted. Furthermore, the insulating film 14 continuously covers the entire back surface S4 side (the entire light incident surface side) of the fixed charge film 13 and the inside of the trench portion 25. As a material of the insulating film 14, for example, silicon oxide (SiO₂), silicon nitride (Si₃N₄), or silicon oxynitride (SiON) can be adopted.

The light shielding film 15 is formed in a lattice shape that opens the light incident surface side of each of the plurality of photoelectric conversion units 23 in a part of the insulating film 14 on a back surface S5 side such that light does not leak into the adjacent pixels 9. Furthermore, the planarization film 16 continuously covers the entire back surface S5 side (the entire light incident surface side) of the insulating film 14 including the light shielding film 15 such that the back surface S1 of the light receiving layer 17 is a planarized surface without unevenness.

The color filter layer 18 includes color filters 26 on the back surface S1 side (light incident surface side) of the planarization film 16 for every 2×2 photoelectric conversion units 23 (hereinafter, also referred to as “photoelectric conversion unit group 27”). Each of the color filters 26 is configured to transmit light of a specific wavelength such as red light, green light, or blue light, and cause the transmitted incident light to be incident on the photoelectric conversion units 23. Furthermore, the color filters 26 are arrayed in a Bayer array in a case of being viewed from the microlens array 19 side.

Furthermore, a partition wall 28 is formed between the adjacent color filters 26. A height of the partition wall 28 is set to the same height as a height of the color filter 26. As a material of the partition wall 28, for example, a low-refractive material having a lower refractive index than the color filters 26 can be adopted. Therefore, a waveguide can be formed with the color filter 26 as a core and the partition wall 28 as a cladding, and diffusion of incident light in the color filter 26 can be prevented.

Note that the example in which the 2×2 photoelectric conversion units 23 are used as the photoelectric conversion unit group 27 has been described in the first embodiment, but other configurations can also be adopted. For example, n×1, 1×m, and n×m (n and m are natural numbers of two or more) photoelectric conversion units 23 may be used as the photoelectric conversion unit group 27.

Furthermore, the microlens array 19 includes a flat bottom portion 29 formed on a back surface S6 side (light incident surface side) of the color filter layer 18, and a plurality of microlenses 30 formed on a back surface S7 side (light incident surface side) of the bottom portion 29. As depicted in FIG. 4, each of the microlenses 30 is formed for each of the photoelectric conversion unit groups 27. Each of the microlenses 30 is configured to condense image light (incident light) from a subject into the photoelectric conversion units 23. Furthermore, the microlens 30 is formed by laminating two or more lens layers having different refractive indexes. Furthermore, out of the two or more lens layers, a lens layer closer to the substrate 2 has a lower refractive index. FIG. 2 illustrates a case where the microlens 30 has a two-layer structure of a first lens layer 31 and a second lens layer 32 that is formed on a back surface S8 side (light incident surface side) of the first lens layer 31 and has a higher refractive index than the first lens layer 31. Note that the first lens layer 31 and the second lens layer 32 are layers that serve as lenses that condense incident light, which is different from an antireflection film and the like.

Specifically, the first lens layer 31 is formed in a hemispherical shape at a position corresponding to a central portion of each of the photoelectric conversion unit groups 27 on the back surface S7 side of the bottom portion 29. The first lens layer 31 has such a size that does not come into contact with the adjacent first lens layer 31. As a material of the first lens layer 31, for example, a material having a low refractive index can be adopted. Examples of the material having a low refractive index include a silicon nitride (SiN), silicon oxynitride (SiON), or titanium oxide (TiO₂) filler-containing resin having a refractive index of 1.15 to 1.55. Since the material having a low refractive index is used, the lens power can be reduced on the substrate 2 side of the microlens 30, and incident light traveling to a center side of the photoelectric conversion unit group 27 can be directed to an outer peripheral side of the photoelectric conversion unit group 27. Therefore, a light-condensed spot 33 can be enlarged, and an inter-same-color sensitivity difference can be reduced even in a case where a variation in a width of the pixel separation portion 24, a variation in a position of the pixel separation portion 24, or an overlay deviation between the pixel separation portion 24 and the microlens 30 occurs.

Furthermore, the second lens layer 32 is formed in a dome shape that covers the entire back surface S8 side of the first lens layer 31 and the bottom portion 29. That is, an outer peripheral portion of a lens layer (the first lens layer 31 in the example of FIG. 2) on the substrate 2 side out of the two or more lens layers is covered with the remaining lens layer (the second lens layer 32 in the example of FIG. 2). Therefore, a side portion of the microlens 30 can be covered with the second lens layer 32, and incident light incident on the side portion of the microlens 30, that is, the incident light that is hardly taken into the photoelectric conversion unit group 27 can be refracted to the center side of the photoelectric conversion unit group 27, and the quantum efficiency can be improved. Furthermore, lens layers (the second lens layers 32 in the example of FIG. 2) on the outermost surface side of the adjacent microlenses 30 are in contact with each other. Since the lens layers on the outermost surface side are in contact with each other, a gap between the microlenses 30 can be reduced, and thus, the incident light can be more reliably condensed by the microlenses 30, and the quantum efficiency can be improved.

Furthermore, an outer peripheral portion of the dome-shaped second lens layer 32 is integrated with that of the adjacent second lens layer 32. That is, in a cross section perpendicular to the back surface S3 (light incident surface) of the substrate 2 and parallel to a row direction of the pixels 9, a total value of a distance a from a central portion of a lower end portion of the first lens layer 31 to an inner peripheral portion of a lower end portion of the second lens layer 32 and a thickness b of the lower end portion of the second lens layer 32 is the same as a cell size of the pixel 9 (half length of one side of the pixel 9). In other words, outer peripheral portions of the adjacent microlenses 30 are in contact with each other. When the outer peripheral portions of the adjacent microlenses 30 are in contact with each other, the gap between the microlenses 30 can be reduced, the incident light can be more reliably condensed by the microlenses 30, and the quantum efficiency can be improved.

As a material of the second lens layer 32, for example, a material having a higher refractive index than the material of the first lens layer 31 can be adopted. Examples of the material having a high refractive index include silicon oxynitride (SiON) having a refractive index of 1.55 to 2.10. Since the material having a high refractive index is used, the lens power can be improved on the outermost surface side of the microlens 30, and the incident light immediately after entering the microlens 30 can be greatly refracted to the center side of the photoelectric conversion unit group 27. Therefore, the incident light can be more reliably taken into the photoelectric conversion unit group 27, and the quantum efficiency can be improved. More specifically, in a case where the partition wall 28 depicted in FIG. 2 is provided between the color filters 26, there is a possibility that the incident light reaches the microlens 30 side of the partition wall 28 so that a part of the incident light is blocked by the partition wall 28. In regard to this, when the refractive index of the second lens layer 32 is high, the incident light can be greatly refracted to the center side of the photoelectric conversion unit group 27 to prevent the incident light from reaching the microlens 30 side of the partition wall 28, and the possibility that a part of the incident light is blocked by the partition wall 28 can be suppressed.

Note that FIG. 2 depicts the example in which the microlens 30 has the two-layer structure of the first lens layer 31 and the second lens layer 32, and the refractive index of the first lens layer 31 is set to be lower than the refractive index of the second lens layer 32, but other configurations can also be adopted. For example, in a case where a lens layer of the microlens 30 has a structure including three or more layers, a configuration may be adopted in which a refractive index gradually decreases from a lens layer on the outermost surface side of the microlens 30 toward a lens layer on the substrate 2 side. That is, among the two or more lens layers, the lens layer closer to the substrate 2 may have a lower refractive index.

Furthermore, a first antireflection film 34 is formed on the outermost surface of the microlens 30. As the first antireflection film 34, for example, a single-layer film or a multilayer film can be adopted. In a case where a single-layer film is adopted, for example, a material having a refractive index between a refractive index of air and a refractive index of the lens layer (the second lens layer 32 in the example of FIG. 2) on the outermost surface side of the microlens 30 can be adopted as a material of the first antireflection film 34. Specific examples thereof include silicon oxynitride (SiON) and a low-temperature oxide film (LTO). Furthermore, in a case where a multilayer film is adopted as the first antireflection film 34, for example, a multilayer film in which a high-refractive-index film and a low-refractive-index film having a lower refractive index than the high-refractive-index film are alternately laminated can be adopted. Here, as depicted in FIG. 2, in a case where the microlens 30 has the configuration in which two or more lens layers are laminated, interfaces increase in the microlens 30, and thus, there is a possibility that a transmittance of incident light decreases. In regard to this, when the first antireflection film 34 is formed on the outermost surface of the microlens 30, reflection of the incident light on the outermost surface of the microlens 30 can be suppressed, and the transmittance of the incident light in the lens layer (second lens layer 32) on the outermost surface side of the microlens 30 can be increased. Therefore, the decrease in the transmittance of the incident light can be suppressed in the microlens 30 as a whole.

Furthermore, a second antireflection film 35 is formed between two adjacent lens layers (the first lens layer 31 and the second lens layer 32 in the example of FIG. 2). As the second antireflection film 35, for example, a single layer film or a multilayer film can be adopted. In a case where a single-layer film is adopted, as a material of the second antireflection film 35, for example, a material having a refractive index within a range between one of refractive indexes of the two adjacent lens layers, that is, two lens layers sandwiching the second antireflection film set as an upper limit value and the other set as a lower limit value can be adopted. Examples of the material of the second antireflection film 35 include silicon oxynitride (SiON). Furthermore, in a case where a multilayer film is adopted as the second antireflection film 35, for example, a multilayer film in which a high-refractive-index film and a low-refractive-index film having a lower refractive index than the high-refractive-index film are alternately laminated can be adopted. When the second antireflection film 35 is formed, reflection of incident light at an interface between two adjacent lens layers (the first lens layer 31 and the second lens layer 32) can be suppressed, and a transmittance of incident light in the lens layer (first lens layer 31) on the substrate 2 side can be increased. Therefore, the decrease in the transmittance of the incident light can be suppressed in the microlens 30 as a whole.

Note that FIG. 2 depicts the example in which the microlens 30 has the two-layer structure of the first lens layer 31 and the second lens layer 32 and the second antireflection film is formed between the first lens layer 31 and the second lens layer 32, that is, between all the lens layers, but other configurations can also be adopted. For example, in a case where a lens layer of the microlens 30 has a structure including three or more layers, the second antireflection film 35 may be formed only between some lens layers.

The wiring layer 21 is formed on the front surface S2 side of the substrate 2 and includes an interlayer insulating film 36 and wirings 37 laminated in a plurality of layers with the interlayer insulating film 36 interposed therebetween. Then, the wiring layer 21 drives the pixel transistor forming each of the pixels 9 via the plurality of layers of wirings 37.

The support substrate 22 is formed on a surface of the wiring layer 21 on a side opposite to a side facing the substrate 2. The support substrate 22 is a substrate configured to secure the strength of the substrate 2 at a manufacturing step of the solid-state imaging device 1. As a material of the support substrate 22, for example, silicon (Si) can be used.

In the solid-state imaging device 1 having the above configuration, light is emitted from the back surface S1 side of the substrate 2 (the back surface S1 side of the light receiving layer 17), the emitted light is transmitted through the microlens 30 and the color filter 26, and the transmitted light is photoelectrically converted by the photoelectric conversion unit 23, thereby a signal charge is generated. Then, the generated signal charge is output as a pixel signal by the vertical signal line 11 depicted in FIG. 1 formed by the wirings 37 via the pixel transistor or the like formed on the front surface S2 side of the substrate 2.

Furthermore, the solid-state imaging device 1 according to the first embodiment has a back-surface irradiation type structure, that is, the structure in which incident light is incident from the back surface S3 side of the substrate 2 with, as the light incident surface, the back surface S3 of the substrate 2 on the side opposite to the front surface S2 of the substrate 2 on which the wiring layer 21 is formed. Therefore, the incident light is incident on the photoelectric conversion unit 23 without being restricted by the wiring layer 21. Therefore, an opening of the photoelectric conversion unit 23 can be made wide, and it is possible to achieve higher sensitivity than that of a front-surface irradiation type, for example.

### [1-3 Method for Manufacturing Microlens]

Next, a method for manufacturing the microlens 30 will be described.

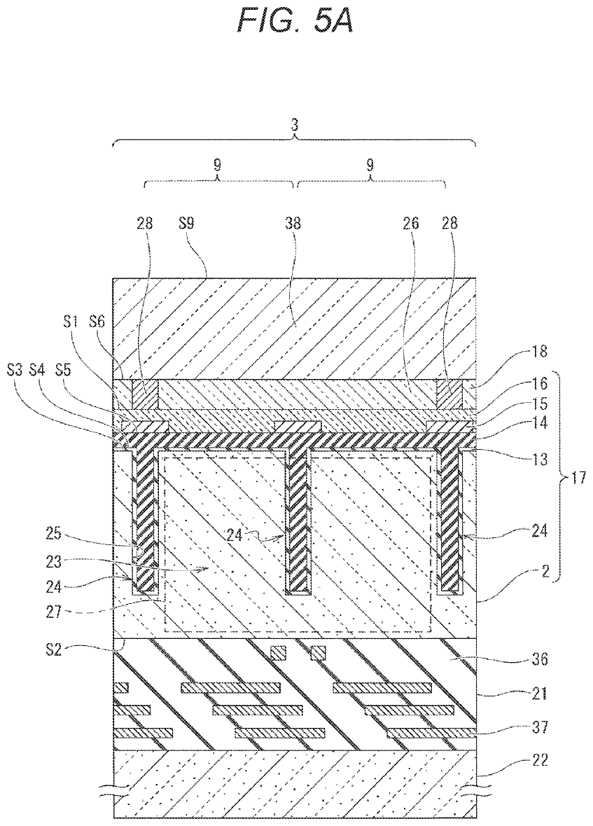

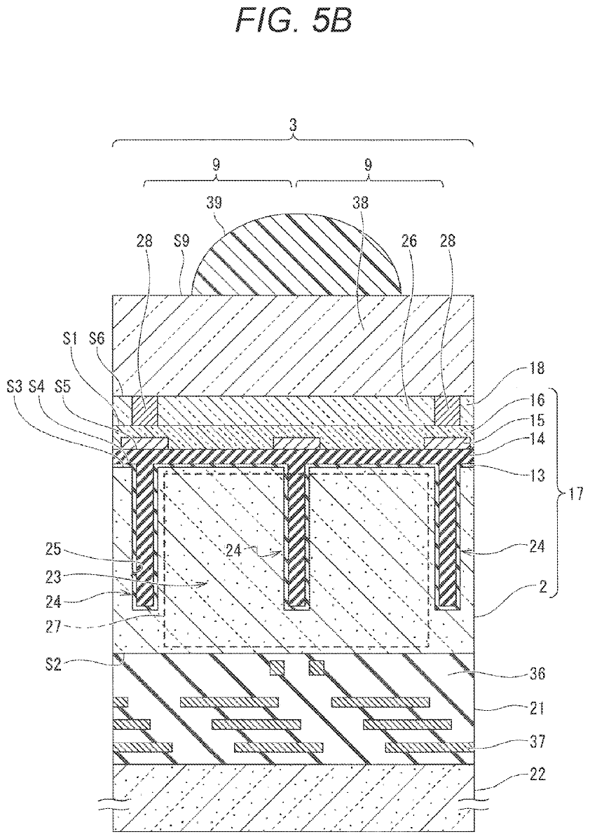

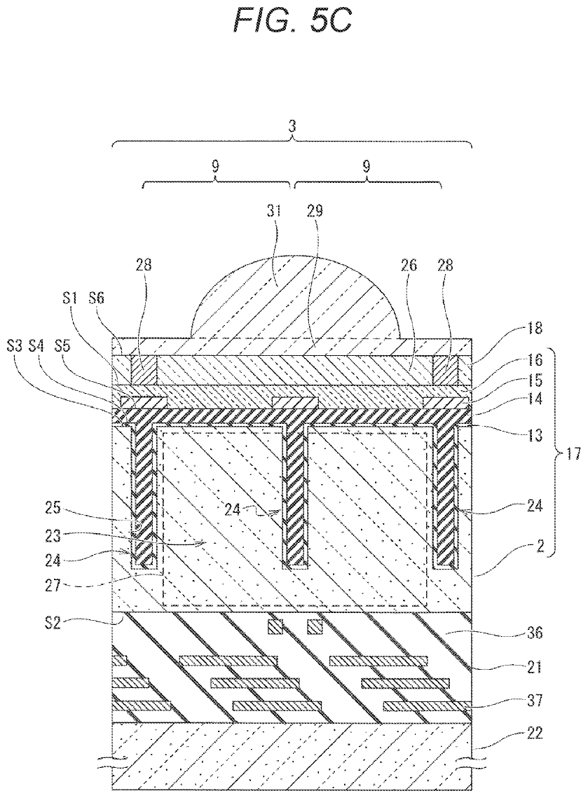

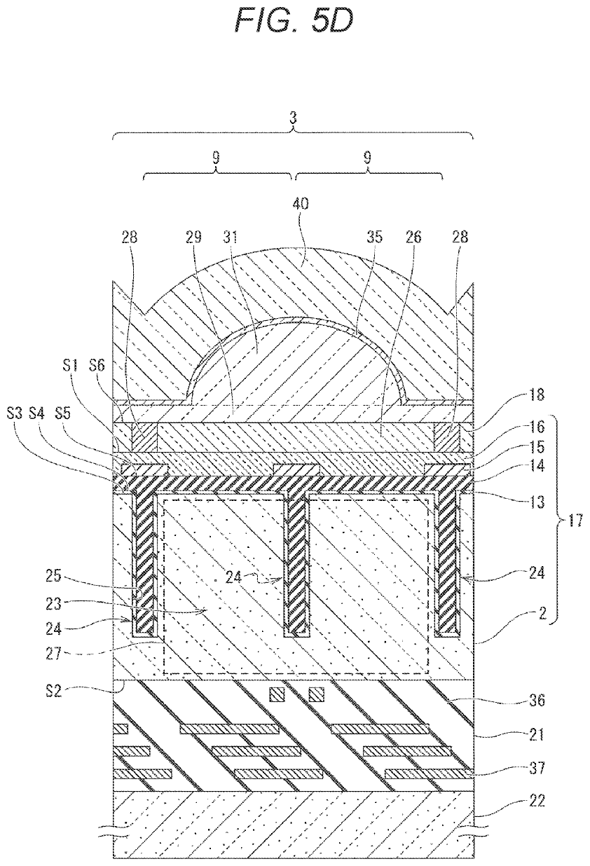

First, as depicted in FIG. 5A, the photoelectric conversion unit 23, the pixel separation portion 24, the color filter 26, the partition wall 28, and the like are formed on the substrate 2, and then, a thick film (hereinafter, also referred to as a “low-N layer 38”) including the material of the first lens layer 31 is formed on the back surface S3 of the substrate 2. As a method for forming the low-N layer 38, for example, a spin coating method or a chemical vapor deposition (CVD) method can be adopted.

Subsequently, as depicted in FIG. 5B, a resist pattern material layer is formed, respectively, at each position corresponding to the first lens layer 31 on the back surface S9 of the low-N layer 38, and then, the resist pattern material layer is subjected to reflow to form a lens pattern layer 39. Subsequently, etching is performed using the lens pattern layer 39 as an etching mask to transfer a shape of the lens pattern layer 39 to the low-N layer 38. As the etching, for example, dry etching can be adopted. Therefore, the bottom portion 29 of the microlens array 19 and the first lens layer 31 are formed as depicted in FIG. 5C. The first lens layer 31 has such a size that an inter-lens gap with the adjacent first lens layer 31 is not filled.

Subsequently, as depicted in FIG. 5D, the second antireflection film 35 is formed on the entire surface of the first lens layer 31, and then, a thick film (hereinafter, also referred to as a “high-N layer 40”) including the material of the second lens layer 32 is formed. As a method for forming the high-N layer 40, for example, a CVD method or the like can be adopted. Subsequently, the entire surface of the high-N layer 40 is etched without using an etching mask to set a thickness of the high-N layer 40 to a desired thickness. That is, the high-N layer 40 is subjected to etch-back. Therefore, the second lens layer 32 is formed, and the microlens array 19 including the microlens 30 in which the first lens layer 31 and the second lens layer 32 are laminated is formed. Subsequently, the first antireflection film 34 is formed on the entire surface of the microlens array 19, whereby the solid-state imaging device 1 depicted in FIG. 2 is completed.

As described above, the microlens 30 is formed by laminating the two or more lens layers (the first lens layer 31 and the second lens layer 32) having different refractive indexes in the solid-state imaging device 1 according to the first embodiment. Furthermore, out of the two or more lens layers (the first lens layer 31 and the second lens layer 32), the lens layer (first lens layer 31) closer to the substrate 2 has a lower refractive index.

Since the material having a higher refractive index is used on the outermost surface side of the microlens 30 in this manner, the lens power can be improved, and incident light immediately after entering the microlens 30 can be greatly refracted to the center side of the photoelectric conversion unit group 27. Therefore, the incident light can be more reliably taken into the photoelectric conversion unit group 27, and the quantum efficiency can be improved. Furthermore, since the material having a lower refractive index is used on the substrate 2 side of the microlens 30, the lens power can be reduced, and incident light traveling to the center side of the photoelectric conversion unit group 27 can be refracted to the outer peripheral side of the photoelectric conversion unit group 27. Therefore, the light-condensed spot 33 can be widened, and the inter-same-color sensitivity difference can be reduced even in the case where the variation in the width of the pixel separation portion 24, the variation in the position of the pixel separation portion 24, or the overlay deviation between the pixel separation portion 24 and the microlens 30 occurs. Therefore, it is possible to provide the solid-state imaging device 1 capable of improving the quantum efficiency while reducing the inter-same-color sensitivity difference.

### [1-4 Modified Examples]

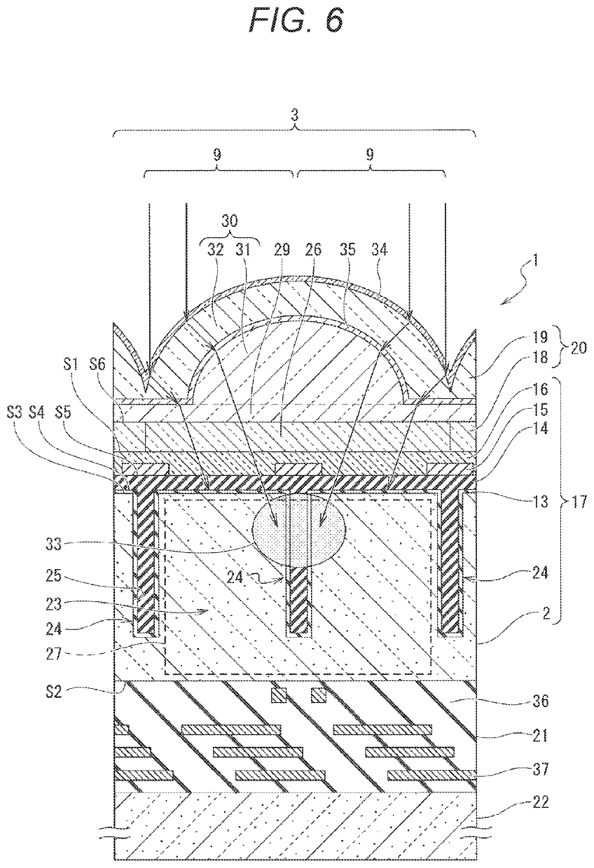

(1) Note that the example in which the partition wall 28 is formed between the color filters 26 has been described in the first embodiment, but other configurations can also be adopted. For example, as depicted in FIG. 6, the partition wall 28 may be omitted. In a case where the partition wall 28 is omitted, incident light is not blocked on the microlens 30 side of the partition wall 28, but the incident light is blocked by the pixel separation portion 24 when the incident light reaches a surface of the pixel separation portion 24 on the microlens 30 side. Therefore, it is necessary to set a refractive index of the second lens layer 32 and the like such that the incident light does not reach the microlens 30 side of the partition wall 28.

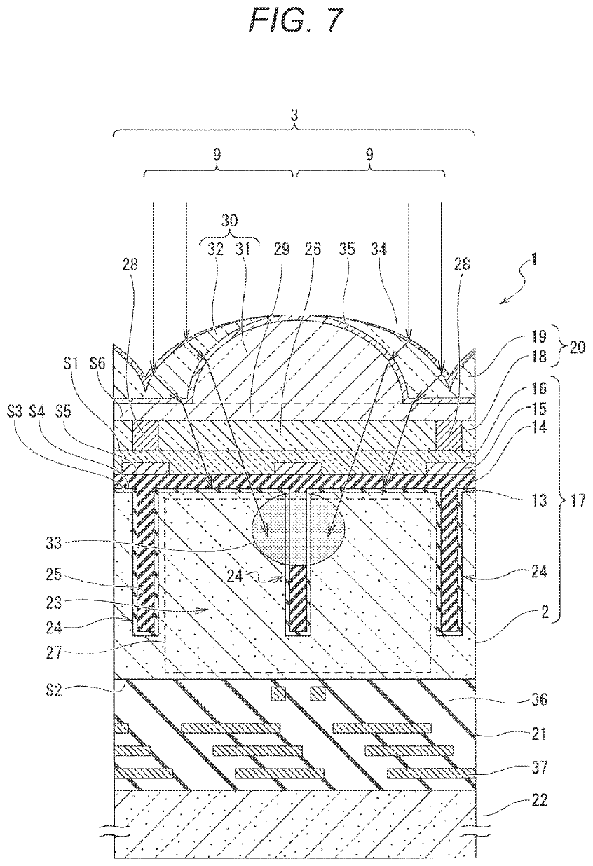

(2) Furthermore, the example in which the shape of the second lens layer 32 is the dome shape covering the entire light incident surface side of the first lens layer 31 has been described in the first embodiment, but other configurations can also be adopted. For example, as depicted in FIG. 7, a shape in which an opening portion is provided at a top portion and a part excluding the top portion is covered may be adopted. With the shape covering the part excluding the top portion, incident light incident on the top portion of the microlens 30, that is, the incident light near the center of the photoelectric conversion unit group 27 can be prevented from being greatly refracted to the center side of the photoelectric conversion unit group 27, and the light-condensed spot 33 can be more reliably enlarged.

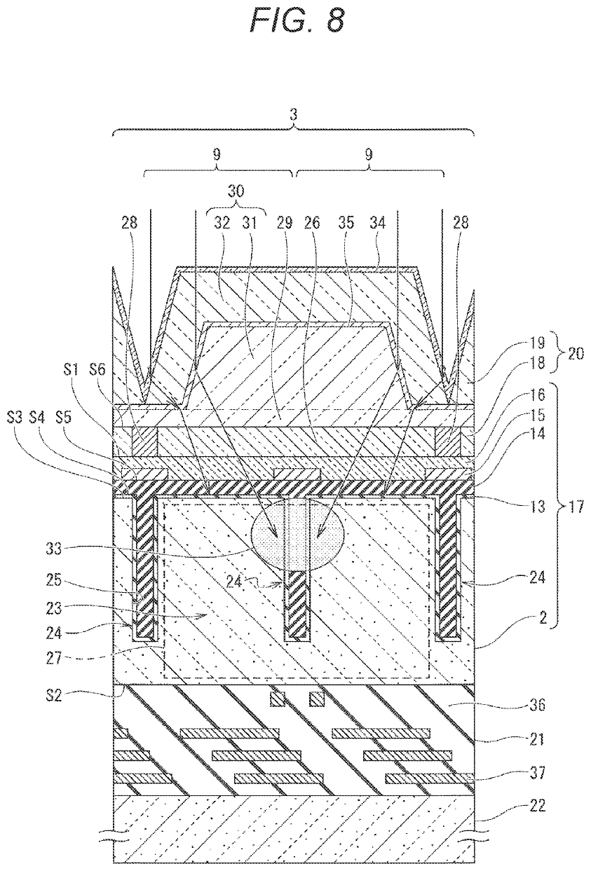

(3) Furthermore, the example in which the shape of the microlens 30 is the hemispherical shape has been described in the first embodiment, but other configurations can also be adopted. For example, as depicted in FIG. 8, a top portion may have a frustum shape (a three-dimensional body obtained by cutting a cone along a plane parallel to a bottom surface and removing a part including a top point) parallel to the light incident surface (back surface S3) of the substrate 2. As the frustum shape, for example, an n-sided frustum (n is a natural number of four or more) or a cone frustum can be adopted. In other words, it is possible to adopt a shape in which a cross-sectional shape of the microlens 30 is trapezoidal in the cross section perpendicular to the back surface S3 (light incident surface) of the substrate 2 and parallel to the row direction of the pixels 9. Since the frustum shape is adopted, incident light incident on the top portion of the microlens 30, that is, the incident light near the center of the photoelectric conversion unit group 27 can be prevented from being greatly refracted to the center side of the photoelectric conversion unit group 27, and the light-condensed spot 33 can be more reliably enlarged.

In the case where the shape of the microlens 30 is the frustum shape, first, a resist pattern material is applied to the entire back surface S9 of the low-N layer 38, and then, defocusing is performed at the time of resist exposure to form the lens pattern layer 39 having a tapered shape at each position corresponding to the first lens layer 31. Subsequently, dry etching is performed using the lens pattern layer 39 as an etching mask to transfer a shape of the lens pattern layer 39 to the low-N layer 38, thereby forming the first lens layer 31.

### 2. Example of Application to Electronic Apparatus

### [2-1 Overall Configuration of Electronic Apparatus]

The technology according to the present disclosure (present technology) may be applied to various electronic apparatuses.

FIG. 9 is a block diagram depicting a configuration example of an embodiment of an imaging device (video camera or digital still camera) as an electronic apparatus to which the present disclosure is applied.

As depicted in FIG. 9, an imaging device 1000 includes a lens group 1001, the solid-state imaging element 1002 (the solid-state imaging device 1 of the first embodiment), a digital signal processor (DSP) circuit 1003, a frame memory 1004, a display section 1005, a recording section 1006, an operation section 1007, and a power supply section 1008. The DSP circuit 1003, the frame memory 1004, the display section 1005, the recording section 1006, the operation section 1007, and the power supply section 1008 are connected to one another via a bus line 1009.

The lens group 1001 takes incident light (image light) from a subject, guides the light to the solid-state imaging element 1002, and forms an image on a light receiving surface (pixel region) of the solid-state imaging element 1002.

The solid-state imaging element 1002 is configured using the CMOS image sensor according to the first embodiment described above. The solid-state imaging element 1002 converts a light amount of the incident light whose image has been formed on an imaging surface by the lens group 1001 into an electric signal in units of pixels, and supplies the electric signal to the DSP circuit 1003 as a pixel signal.

The DSP circuit 1003 performs predetermined image processing on the pixel signal supplied from the solid-state imaging element 1002. Then, the DSP circuit 1003 supplies image signals after the image processing to the frame memory 1004 in units of frames, and temporarily stores the image signals in the frame memory 1004.

The display section 1005 is configured using, for example, a panel display device such as a liquid crystal panel or an organic electro luminescence (EL) panel. The display section 1005 displays an image (moving image) of the subject on the basis of the pixel signals in units of frames temporarily stored in the frame memory 1004.

The recording section 1006 is configured using a DVD, a flash memory, and the like. The recording section 1006 reads and records the pixel signals in units of frames temporarily stored in the frame memory 1004.

The operation section 1007 issues operation commands for various functions of the imaging device 1000 under operations of a user.

The power supply section 1008 appropriately supplies power to each part of the imaging device 100, such as the DSP circuit 1003, the frame memory 1004, the display section 1005, the recording section 1006, and the operation section 1007.

### [2-2 Usage Examples of CMOS Image Sensor]

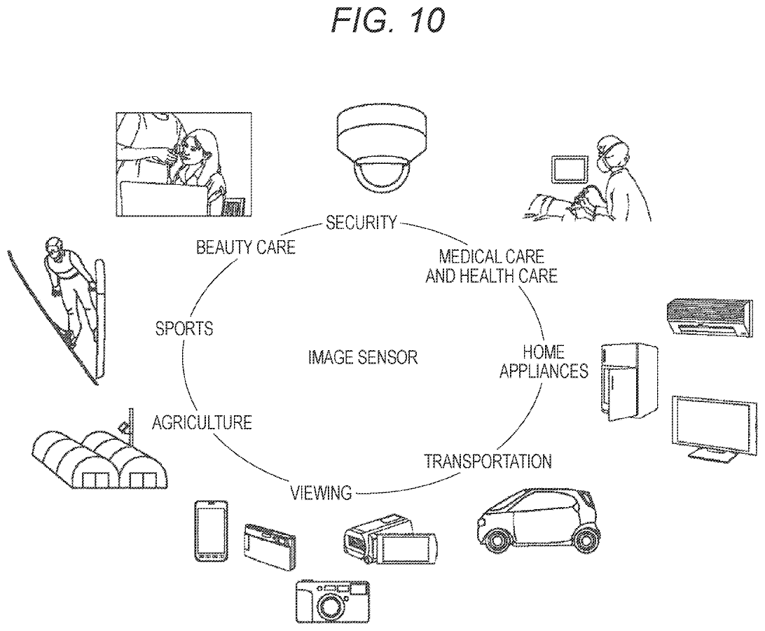

Note that the electronic apparatus to which the present technology is applied only needs to be a device using a CMOS image sensor as an image capturing unit, and can be used, for example, in various cases of sensing light such as visible light, infrared light, ultraviolet light, and X-rays as follows, in addition to the imaging device 1000.
As depicted in FIG. 10, a device that captures an image for use in viewing, such as a digital camera or a portable apparatus equipped with a camera function
A device used in transportation, such as a vehicle-mounted sensor that captures images of a front, a rear, surroundings, an interior, and the like of a vehicle, a monitoring camera that monitors traveling vehicles and roads, or a range-finding sensor that measures a distance between vehicles and the like, for safety driving such as automatic stop, recognition of a state of a driver state, and the like
A device used for home appliances such as a TV, a refrigerator, and an air conditioner, to capture an image of a gesture of a user and operate such an appliance in accordance with the gesture
A device used for medical care and health care, such as an endoscope or a device that performs angiography by receiving infrared light
A device used for security, such as a monitoring camera for a crime prevention application or a camera for a person authentication application
A device used for beauty care, such as a skin measuring instrument that captures an image of a skin or a microscope that captures an image of a scalp
A device used for sports, such as an action camera or a wearable camera for sports applications and the like
A device used for agriculture, such as a camera for monitoring states of fields and crops

### 3. Example of Application to Mobile Body

The technology according to the present disclosure (present technology) may be achieved, for example, as a device mounted on any type of mobile body such as an automobile, an electric vehicle, a hybrid electric vehicle, a motorcycle, a bicycle, a personal mobility, an airplane, a drone, a ship, and a robot.

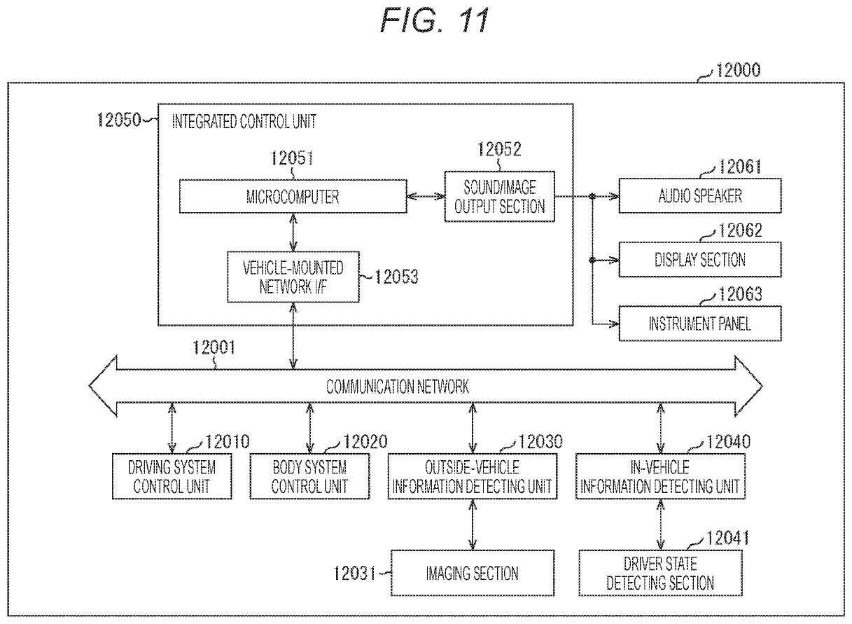

FIG. 11 is a block diagram depicting an example of a schematic configuration of a vehicle control system as an example of a mobile body control system to which the technology according to the present disclosure can be applied.

The vehicle control system 12000 includes a plurality of electronic control units connected to each other via a communication network 12001. In the example depicted in FIG. 11, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

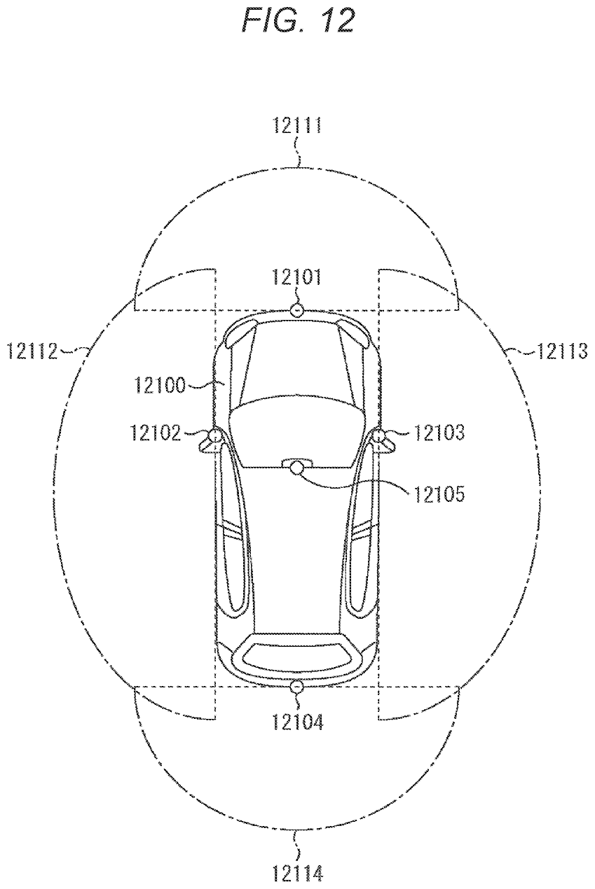

FIG. 12 is a diagram depicting an example of the installation position of the imaging section 12031.

In FIG. 12, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. An image of the front acquired by the imaging sections 12101 and 12105 is mainly used to detect a preceding vehicle, a pedestrian, an obstacle, a traffic light, a traffic sign, a lane, and the like.

Note that FIG. 12 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described as above. The technology according to the present disclosure can be applied to the imaging section 12031 among the above-described configurations. Specifically, the solid-state imaging device 1 in FIG. 1 can be applied to the imaging section 12031. When the technology according to the present disclosure is applied to the imaging section 12031, a more favorable imaged image can be obtained, so that the fatigue of the driver can be reduced.

### 4. Example of Application to Endoscopic Surgery System

The technology according to the present disclosure (the present technology) may be applied to, for example, an endoscopic surgery system.

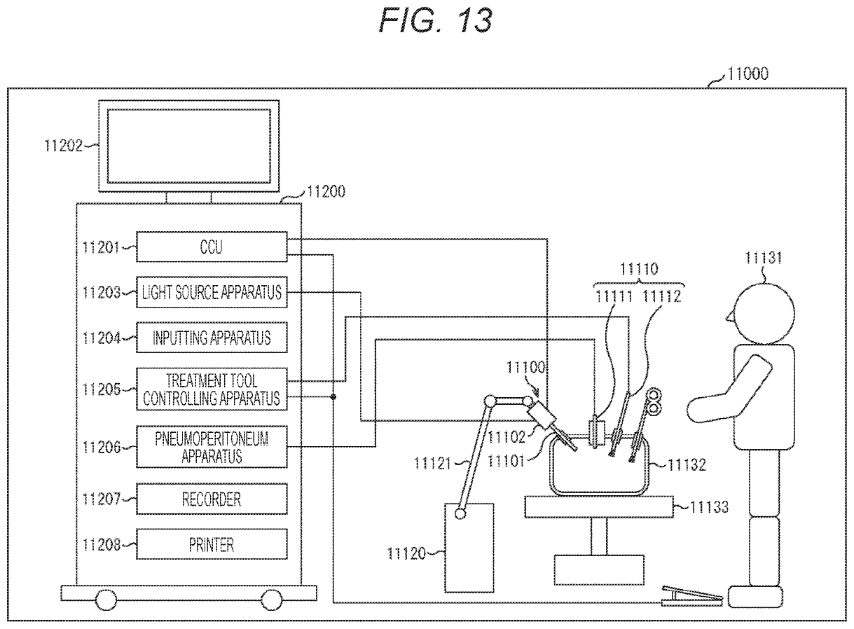

FIG. 13 is a view depicting an example of a schematic configuration of the endoscopic surgery system to which the technology according to the embodiment of the present disclosure (present technology) can be applied.

In FIG. 13, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

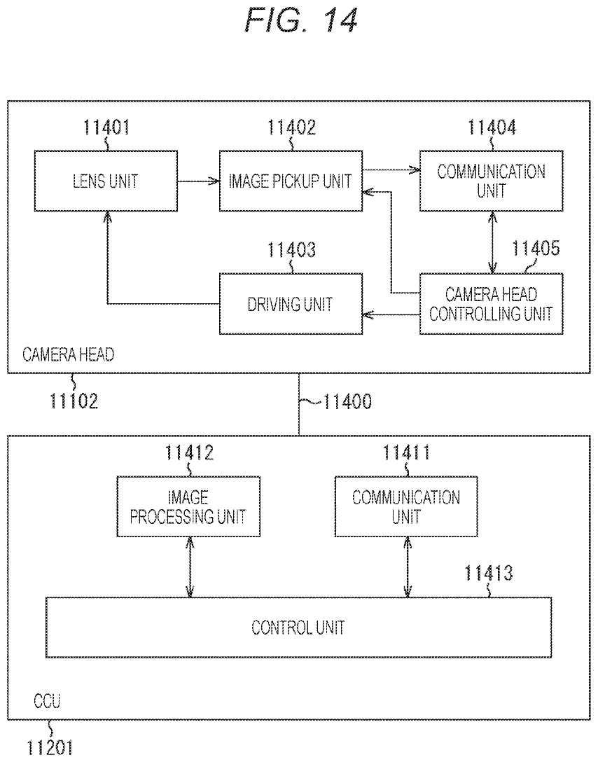

FIG. 14 is a block diagram depicting an example of a functional configuration of the camera head 11102 and the CCU 11201 depicted in FIG. 13.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described as above. The technology according to the present disclosure can be applied to the image pickup unit 11402 among the above-described configurations. Specifically, the solid-state imaging device 1 in FIG. 1 can be applied to an image pickup unit 10402. When the technology according to the present disclosure is applied to the image pickup unit 10402, a clearer image of the surgical region can be obtained, and thus, the surgeon can reliably confirm the surgical region.

Note that, here, the endoscopic surgery system has been described as an example, but the technology according to the present disclosure may be applied to, for example, a microscopic surgery system or the like.

Note that the present technology can also have the following configurations.

(1)

A solid-state imaging device including:
a substrate;
a plurality of photoelectric conversion units formed on the substrate;
a microlens array including a plurality of microlenses formed on one surface side of the substrate for a photoelectric conversion unit group including at least two or more of the adjacent photoelectric conversion units; and
a trench portion which has a lattice shape and is formed in the substrate to surround each of the photoelectric conversion units,
in which two or more lens layers having different refractive indexes are laminated in the microlens, and
a lens layer closer to the substrate out of the two or more lens layers has a lower refractive index.

(2)

The solid-state imaging device according to (1), further including
a first antireflection film formed on an outermost surface of the microlens.

(3)

The solid-state imaging device according to (1) or (2), further including
a second antireflection film formed between two adjacent lens layers.

(4)

The solid-state imaging device according to any one of (1) to (3), in which
out of the two or more lens layers, an outer peripheral portion of a lens layer on the substrate side is covered with a remaining lens layer.

(5)

The solid-state imaging device according to (4), in which
the remaining lens layer covers a front surface excluding a top portion of the lens layer on the substrate side.

(6)

The solid-state imaging device according to (4) or (5), in which
outer peripheral portions of the microlenses, which are adjacent, are in contact with each other.

(7)

The solid-state imaging device according to any one of (1) to (6), in which
the microlens has a frustum shape whose top portion is parallel to a light incident surface of the substrate.

(8)

The solid-state imaging device according to any one of (1) to (7), further including
a color filter layer including a plurality of color filters formed between the microlens array and the substrate for the photoelectric conversion unit group,
in which the color filter layer includes a partition wall formed between the color filters.

(9)

An electronic apparatus including a solid-state imaging device, in which
the solid-state imaging device includes: a substrate; a plurality of photoelectric conversion units formed on the substrate; a microlens array including a plurality of microlenses formed on one surface side of the substrate for a photoelectric conversion unit group including at least two or more of the adjacent photoelectric conversion units; and a trench portion which has a lattice shape and is formed in the substrate to surround each of the photoelectric conversion units,
two or more lens layers having different refractive indexes are laminated in the microlens, and
a lens layer closer to the substrate out of the two or more lens layers has a lower refractive index.

### REFERENCE SIGNS LIST

1 Solid-state imaging device
2 Substrate
3 Pixel region
4 Vertical drive circuit
5 Column signal processing circuit
6 Horizontal drive circuit
7 Output circuit
8 Control circuit
9 Pixel
10 Pixel driving wiring
11 Vertical signal line
12 Horizontal signal line
13 Fixed charge film
14 Insulating film
15 Light shielding film
16 Planarization film
17 Light receiving layer
18 Color filter layer
19 Microlens array
20 Light condensing layer
21 Wiring layer
22 Support substrate
23 Photoelectric conversion unit
24 Pixel separation portion
25 Trench portion
26 Color filter
27 Photoelectric conversion unit group
28 Partition wall
29 Bottom portion
30 Microlens
31 First lens layer
32 Second lens layer
33 Light-condensed spot
34 First antireflection film
35 Second antireflection film
36 Interlayer insulating film
37 Wiring
38 Low-N layer
39 Lens pattern layer
1000 High-N layer
1000 Imaging device
1001 Lens group
1002 Solid-state imaging element
1003 DSP circuit
1004 Frame memory
1005 Display section
1006 Recording section
1007 Operation section
1008 Power supply section
1009 Bus line

What is claimed is:

1. A solid-state imaging device, comprising:
a substrate;
a plurality of photoelectric conversion units formed on the substrate;
a microlens array including a plurality of microlenses formed on one surface side of the substrate for a photoelectric conversion unit group including at least two or more of the adjacent photoelectric conversion units; and
a trench portion which has a lattice shape and is formed in the substrate to surround each of the photoelectric conversion units,
wherein two or more lens layers having different refractive indexes are laminated in the microlens, and
a lens layer closer to the substrate out of the two or more lens layers has a lower refractive index.

2. The solid-state imaging device according to claim 1, further comprising
a first antireflection film formed on an outermost surface of the microlens.

3. The solid-state imaging device according to claim 1, further comprising
a second antireflection film formed between two adjacent lens layers out of the two or more lens layers.

4. The solid-state imaging device according to claim 1, wherein
out of the two or more lens layers, an outer peripheral portion of a lens layer on a side of the substrate is covered with a remaining lens layer.

5. The solid-state imaging device according to claim 4, wherein
the remaining lens layer covers a front surface excluding a top portion of the lens layer on the side of the substrate.

6. The solid-state imaging device according to claim 4, wherein
outer peripheral portions of the microlenses, which are adjacent, are in contact with each other.

7. The solid-state imaging device according to claim 1, wherein
the microlens has a frustum shape whose top portion is parallel to a light incident surface of the substrate.

8. The solid-state imaging device according to claim 1, further comprising
a color filter layer including a plurality of color filters formed between the microlens array and the substrate for the photoelectric conversion unit group,
wherein the color filter layer includes a partition wall formed between the color filters.

9. An electronic apparatus comprising a solid-state imaging device, wherein
the solid-state imaging device includes: a substrate; a plurality of photoelectric conversion units formed on the substrate; a microlens array including a plurality of microlenses formed on one surface side of the substrate for a photoelectric conversion unit group including at least two or more of the adjacent photoelectric conversion units; and a trench portion which has a lattice shape and is formed in the substrate to surround each of the photoelectric conversion units,
two or more lens layers having different refractive indexes are laminated in the microlens, and
a lens layer closer to the substrate out of the two or more lens layers has a lower refractive index.
